(19) United States
(12) Patent Application Publication
(10) Pub. No.: US 2023/0395398 A1
(43) Pub. Date: Dec. 7, 2023

(54) FILM, METHOD FOR MANUFACTURING SAME, AND METHOD FOR MANUFACTURING SEMICONDUCTOR PACKAGE

(71) Applicant: AGC Inc., Tokyo (JP)

(72) Inventors: Seigo KOTERA, Tokyo (JP); Satoshi TAKENAKA, Tokyo (JP); Tetsuya HASEGAWA, Tokyo (JP); Takatoshi YAOITA, Tokyo (JP); Masayuki MORINO, Tokyo (JP); Mio TOKUNAGA, Tokyo (JP); Yuki HAYASAKA, Tokyo (JP)

(73) Assignee: AGC Inc., Tokyo (JP)

(21) Appl. No.: 18/450,543

(22) Filed: Aug. 16, 2023

Related U.S. Application Data
(63) Continuation of application No. PCT/JP2021/046391, filed on Dec. 15, 2021.

(30) Foreign Application Priority Data
Feb. 25, 2021 (JP) 2021-028909

(51) Int. Cl. H01L 21/56; H01L 21/306

(52) U.S. Cl. CPC H01L 21/566; H01L 21/306

(57) ABSTRACT

The present invention relates to a film including at least a substrate and an antistatic layer, in which a ratio of a peeled area when a tape peeling test is performed under the following conditions after 300% uniaxial stretching at 25° C. is less than 5%, the tape peeling test is that: Cellotape® is pressure-bonded to a surface of the film on an antistatic layer side using a roller through 5 reciprocations with a load of 4 kg, and the Cellotape® is peeled off at a speed of 100 m/min in a direction of 180° with respect to the film within 5 minutes, thereby obtaining a ratio of a peeled area of the film to an area of an adhesive portion of the Cellotape®.

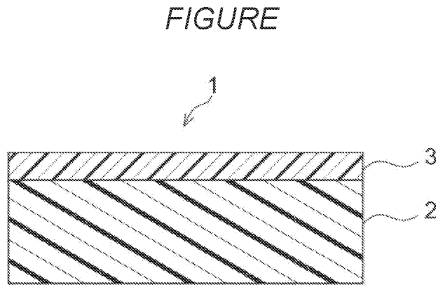

### CROSS-REFERENCE TO RELATED APPLICATIONS

This is a continuation of International Application No. PCT/JP2021/046391 filed on Dec. 15, 2021, and claims priority from Japanese Patent Application No. 2021-028909 filed on Feb. 25, 2021, the entire content of which is incorporated herein by reference.

### TECHNICAL FIELD

The present disclosure relates to a film, a method for manufacturing the same, and a method for manufacturing a semiconductor package.

### BACKGROUND ART

Films used in various industrial fields may be provided with an antistatic layer to prevent charging of the films.

For example, a semiconductor device is encapsulated in a form of a package and mounted on a board in order to block and protect the semiconductor device from outside air. A curable resin such as an epoxy resin is used for encapsulating the semiconductor device. Resin encapsulation is performed by placing the semiconductor device in a predetermined place in a mold, filling the mold with a curable resin, and curing the curable resin. A generally known encapsulating method includes a transfer molding method and a compression molding method. In encapsulation of the semiconductor device, a release film is often placed on an inner surface of the mold in order to improve releasability of the package from the mold. For example, Patent Literatures 1 to 3 describe films suitable for manufacturing a semiconductor package.

When a release film is used for encapsulating a semiconductor device, static electricity is generated when the film is peeled off from a package, and the film is easily charged. The charged film may damage or break the semiconductor package due to discharge. The damaged semiconductor package may have poor resistance to static electricity in a use environment thereof. Therefore, from viewpoints of productivity of the semiconductor package and the resistance to the static electricity in the use environment of the semiconductor package, it is preferable to use a film with an antistatic layer as a release film.

Patent Literature 2 proposes a film containing at least one antistatic agent selected from the group consisting of a conductive polymer and a conductive metal oxide as a release film in manufacture of a semiconductor package.

### CITATION LIST

### Patent Literature

Patent Literature 1: WO2015/133630
Patent Literature 2: WO2016/093178
Patent Literature 3: WO2016/125796

### SUMMARY OF INVENTION

### Technical Problem

On the other hand, there is a demand for a technique for further improving antistatic performance of a film. For example, in recent years, due to demands for miniaturization and thinning of a semiconductor product, there is an increasing need for a reduction in a thickness of a semiconductor package. Accordingly, it is desirable to reduce a thickness of an encapsulating resin. However, it has been found that when the thickness of the encapsulating resin is reduced, a package is likely to be broken due to charge generated when a film is peeled off. Therefore, there is a demand for a film having higher antistatic performance.

In view of such circumstances, the present disclosure relates to providing a film having excellent antistatic performance, a method for manufacturing the same, and a method for manufacturing a semiconductor package using the same.

### Solution to Problem

Means for solving the above problems include the following aspects.
<1> A film including at least a substrate and an antistatic layer,
   in which a ratio of a peeled area when a tape peeling test is performed under the following conditions after 300% uniaxial stretching at 25° C. is less than 5%.
   the tape peeling test is that:
   Cellotape® is pressure-bonded to a surface of the film on an antistatic layer side using a roller through 5 reciprocations with a load of 4 kg, and the Cellotape® is peeled off at a speed of 100 m/min in a direction of 180° with respect to the film within 5 minutes, thereby obtaining a ratio of a peeled area of the film to an area of an adhesive portion of the Cellotape®.
<2> The film according to <1>, in which a relation of (H2-H1)≥0 is satisfied when a wiping test is performed under the following conditions after 300% uniaxial stretching at 25° C.,
   the wiping test is that:
   the film is wiped by rubbing the surface of the film on the antistatic layer side using a nonwoven fabric to which acetone is attached through 20 reciprocations with a load of 4 kg, and hazes before and after the wiping are measured at same position of the film, and a haze before the wiping is denoted by H1, and a haze after the wiping is denoted by H2.
<3> The film according to <1> or <2>, in which O/C is within a range of 0.010 to 0.200 in surface chemical composition analysis of the substrate on an antistatic layer side by X-ray photoelectron spectroscopy.
<4> The film according to any one of <1> to <3>, in which N/F is within a range of 0.010 to 0.100 in surface chemical composition analysis of the substrate on the antistatic layer side by X-ray photoelectron spectroscopy.
<5> A film including at least a substrate and an antistatic layer,
   in which a relation of (H2-H1)≥0 is satisfied when a wiping test is performed under the following conditions after 300% uniaxial stretching at 25° C.,
   the wiping test is that:
   the film is wiped by rubbing a surface of the film on an antistatic layer side using a nonwoven fabric to which acetone is attached through 20 reciprocations with a load of 4 kg, and hazes before and after the wiping are measured at same position of the film, and a haze before the wiping is denoted by H1, and a haze after the wiping is denoted by H2.
<6> The film according to <5>, in which O/C is within a range of 0.010 to 0.200 in surface chemical composition analysis of the substrate on an antistatic layer side by X-ray photoelectron spectroscopy.
<7> The film according to <5> or <6>, in which N/F is within a range of 0.010 to 0.100 in surface chemical composition analysis of the substrate on the antistatic layer side by X-ray photoelectron spectroscopy.
<8> A film including at least a substrate and an antistatic layer,
   in which O/C is within a range of 0.010 to 0.200 in surface chemical composition analysis of the substrate on an antistatic layer side by X-ray photoelectron spectroscopy.
<9> The film according to <8>, in which N/F is within a range of 0.010 to 0.100 in surface chemical composition analysis of the substrate on the antistatic layer side by X-ray photoelectron spectroscopy.
<10> A film including at least a substrate and an antistatic layer,
   in which N/F is within a range of 0.010 to 0.100 in surface chemical composition analysis of the substrate on an antistatic layer side by X-ray photoelectron spectroscopy.
<11> The film according to any one of <1> to <10>, in which a surface of the substrate on the antistatic layer side is plasma-treated.
<12> The film according to any one of <1> to <11>, in which the substrate includes at least one selected from the group consisting of a fluororesin, polymethylpentene, syndiotactic polystyrene, and a polycycloolefin.
<13> The film according to any one of <1> to <12>, in which the substrate includes at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.
<14> The film according to any one of <1> to <13>, further including an adhesive layer on a surface of the antistatic layer opposite to the substrate.
<15> The film according to any one of <1> to <14>, which is a release film used in a step of encapsulating a semiconductor device with a curable resin.
<16> A method for manufacturing a film, the method including:
   plasma-treating a surface of a substrate, and
   providing an antistatic layer on the plasma-treated substrate or providing an antistatic layer on the plasma-treated substrate via at least a third layer adjacent to the substrate,
   in which in surface chemical composition analysis of the substrate after the plasma treatment on an antistatic layer side by X-ray photoelectron spectroscopy. O/C is within a range of 0.010 to 0.200, N/F is within a range of 0.010 to 0.100, or both ranges of O/C and N/F are satisfied.
<17> The method for manufacturing a film according to <16>, in which the plasma treatment is performed under a presence of an argon gas, an ammonia gas, or a nitrogen gas which may or may not include 10 vol % or less of a hydrogen gas.
<18> The method for manufacturing a film according to <16> or <17>, the method further including corona-treating the surface of the substrate before the plasma treatment.
<19> The method for manufacturing a film according to any one of <16> to <18>, the method further including providing an adhesive layer on a surface of the antistatic layer opposite to the substrate.
<20> A method for manufacturing a semiconductor package, the method including:
   disposing the film according to any one of <1> to <15> or a film manufactured by the manufacturing method according to any one of <16> to <19> on an inner surface of a mold;
   disposing a board including a semiconductor device in the mold in which the film is disposed;
   encapsulating the semiconductor device in the mold with a curable resin to produce an encapsulated body; and
   releasing the encapsulated body from the mold.

### Advantageous Effects of Invention

According to the present disclosure, a film having excellent antistatic performance, a method for manufacturing the same, and a method for manufacturing a semiconductor package using the same are provided.

### BRIEF DESCRIPTION OF DRAWINGS

The FIG. is a schematic cross-sectional view of a film according to one aspect of the present disclosure.

### DESCRIPTION OF EMBODIMENTS

Hereinafter, modes for implementing embodiments of the present disclosure will be described in detail. However, the embodiments of the present disclosure are not limited to the following embodiments. In the following embodiments, constituent elements (including element steps and the like) are not essential unless otherwise specified. The same applies to numerical values and ranges thereof, which do not limit the embodiments of the present disclosure.

In the present disclosure, the term “step” includes not only a step that is independent of other steps, but also a step that cannot be clearly distinguished from other steps, as long as the purpose of the step is achieved.

In the present disclosure, a numerical value range indicated by using “to” includes numerical values described before and after “to” as a minimum value and a maximum value, respectively.

In a numerical value range described in stages in the present disclosure, an upper limit value or a lower limit value described in one numerical value range may be replaced with an upper limit value or a lower limit value of another numerical value range described in stages. In a numerical value range described in the present disclosure, an upper limit value or a lower limit value of the numerical value range may be replaced with values described in Examples.

In the present disclosure, each component may contain a plurality of kinds of corresponding substances. When a plurality of kinds of substances corresponding to each component are present in a composition, a content ratio or content of each component means a total content ratio or content of the plurality of kinds of substances present in the composition unless otherwise specified.

When the embodiments are described in the present disclosure with reference to a drawing, configurations of the embodiments are not limited to configurations shown in the drawing. Sizes of members in the drawing are conceptual, and a relative relationship between the sizes of the members is not limited thereto.

In the present disclosure, a “unit” of a polymer means a portion derived from a monomer that exists in the polymer and constitutes the polymer. A unit obtained by chemically converting a structure of a certain unit after polymer formation is also referred to as a unit. In some cases, a unit derived from an individual monomer is referred to by a name obtained by adding a “unit” to a name of the monomer.

In the present disclosure, a film and a sheet are referred to as a “film” regardless of a thickness thereof.

In the present disclosure, acrylate and methacrylate are collectively referred to as “(meth)acrylate”, and acrylic and methacrylic are collectively referred to as “(meth)acrylic”.

In the present disclosure, films according to first to fourth embodiments may be collectively referred to as a “film of the present disclosure”.

<Film>

The film according to the first embodiment of the present disclosure includes at least a substrate and an antistatic layer, and a ratio of a peeled area when a tape peeling test is performed under the following conditions after 300% uniaxial stretching at 25° C. is less than 5%.

Cellotape® is pressure-bonded to a surface of the film on an antistatic layer side using a roller through 5 reciprocations with a load of 4 kg, and the Cellotape® is peeled off at a speed of 100 m/min in a direction of 180° with respect to the film within 5 minutes, thereby obtaining a ratio of a peeled area of the film to an area of an adhesive portion of the Cellotape®.

Here, the adhesive portion of the Cellotape® refers to a portion of the surface of the film to which the Cellotape® adheres.

The film according to the second embodiment of the present disclosure includes at least a substrate and an antistatic layer, and a relation of (H2-H1)≥0 is satisfied when a wiping test is performed under the following conditions after 300% uniaxial stretching at 25° C.
the film is wiped by rubbing the surface of the film on the antistatic layer side using a nonwoven fabric to which acetone is attached through 20 reciprocations with a load of 4 kg, and hazes before and after the wiping are measured at same position of the film, and a haze before the wiping is denoted by H1, and a haze after the wiping is denoted by H2.

The film according to the third embodiment of the present disclosure includes at least a substrate and an antistatic layer, and O/C is within a range of 0.010 to 0.200 in surface chemical composition analysis of the substrate on an antistatic layer side by X-ray photoelectron spectroscopy.

The film according to the fourth embodiment of the present disclosure includes at least a substrate and an antistatic layer, and N/F is within a range of 0.010 to 0.100 in surface chemical composition analysis of the substrate on an antistatic layer side by X-ray photoelectron spectroscopy.

It was found that the films according to the first to fourth embodiments have excellent antistatic performance. The reason for the above is not necessarily clear, but it is presumed that adhesion of the antistatic layer when the film is stretched contributes to the antistatic performance of the film, and the films according to the first to fourth embodiments have high antistatic performance due to excellent adhesion of the antistatic layer. For example, in a case where the film is stretched, when the antistatic layer has excellent adhesion to an adjacent layer, it is considered that the antistatic layer is less likely to be peeled off or cracked, and a conductive path is easy to be maintained. Accordingly, it is presumed that generated static electricity is easily released to the outside of the substrate, and excellent antistatic performance is obtained.

The film of the present disclosure only needs to include the substrate and the antistatic layer, and other configurations are not particularly limited. A schematic cross-sectional view of a film in one aspect is shown in the FIGURE. A film 1 shown in the FIG. includes an antistatic layer 3 on a substrate 2. The film 1 may include other layers in addition to the substrate 2 and the antistatic layer 3. Hereinafter, each constituent element of the film of the present disclosure will be described in detail.

<Substrate>

A material of the substrate is not particularly limited, and preferably contains a resin. In one aspect, from a viewpoint of releasability of the film, the substrate preferably contains a resin having releasability (hereinafter, also referred to as a “releasable resin”). The releasable resin means a resin in which a layer formed by the resin has releasability. Examples of the releasable resin include a fluororesin, polymethylpentene, syndiotactic polystyrene, a polycycloolefin, a silicone rubber, a polyester elastomer, polybutylene terephthalate, and a non-stretched nylon. From a viewpoint of excellent releasability, heat resistance, strength, and elongation at a high temperature, and the like, a fluororesin, polymethylpentene, syndiotactic polystyrene, and a polycycloolefin are preferred, and from a viewpoint of excellent releasability, a fluororesin is more preferred. The resin contained in the substrate may be used alone or in combination of two or more thereof. The substrate is particularly preferably formed by a fluororesin alone. However, even when the substrate is formed by a fluororesin alone, a resin other than the fluororesin is not prevented from being contained within a range in which effects of the invention are not impaired.

The fluororesin is preferably a fluoroolefin polymer from a viewpoint of excellent releasability and heat resistance. The fluoroolefin polymer is a polymer having a unit based on a fluoroolefin. The fluoroolefin polymer may further have a unit other than the unit based on the fluoroolefin.

Examples of the fluoroolefin include tetrafluoroethylene (TFE), vinyl fluoride, vinylidene fluoride, trifluoroethylene, hexafluoropropylene, and chlorotrifluoroethylene. The fluoroolefin may be used alone or in combination of two or more thereof.

Examples of the fluoroolefin polymer include an ethylene-tetrafluoroethylene copolymer (ETFE), a tetrafluoroethylene-hexafluoropropylene copolymer (FEP), a tetrafluoroethylene-perfluoro(alkyl vinyl ether) copolymer (PFA), and a tetrafluoroethylene-hexafluoropropylene-vinylidene fluoride copolymer (THV). From a viewpoint of mechanical properties, at least one selected from the group consisting of ETFE and FEP is preferred. The fluoroolefin polymer may be used alone or in combination of two or more thereof.

From a viewpoint of large elongation at a high temperature, ETFE is preferred as the fluoroolefin polymer. ETFE is a copolymer having a TFE unit and an ethylene unit (hereinafter, also referred to as an “E unit”).

The ETFE is preferably a polymer having a TFE unit, an E unit, and a unit based on a third monomer other than TFE and ethylene. Depending on a type and a content of the unit based on the third monomer, crystallinity of the ETFE is easily adjusted, and accordingly, a storage elastic modulus or other tensile properties of the substrate is easily adjusted. For example, when the ETFE has the unit based on the third monomer (particularly, a monomer having a fluorine atom), a tensile strength and elongation at a high temperature (particularly, at about 180° C.) tends to be increased.

Examples of the third monomer include a monomer having a fluorine atom and a monomer having no fluorine atoms.

Examples of the monomer having a fluorine atom include the following monomers (a1) to (a5).

Monomer (a1): fluoroolefins each having 2 or 3 carbon atoms.

Monomer (a2): fluoroalkylethylenes represented by X(CF₂)ₙCY═CH₂ (where X and Y each independently represent a hydrogen atom or a fluorine atom, and n is an integer of 2 to 8).

Monomer (a3): fluorovinylethers.

Monomer (a4): functional group-containing fluorovinylethers.

Monomer (a5): a fluorine-containing monomer having an alicyclic structure.

Examples of the monomer (a1) include fluoroethylenes (trifluoroethylene, vinylidene fluoride, vinyl fluoride, chlorotrifluoroethylene, and the like), and fluoropropylenes (hexafluoropropylene (HFP), 2-hydropentafluoropropylene, and the like).

The monomer (a2) is preferably a monomer having n of 2 to 6, and more preferably a monomer having n of 2 to 4. A monomer whose X is a fluorine atom and Y is a hydrogen atom, that is, (perfluoroalkyl)ethylene is preferred.

Specific examples of the monomer (a2) include the following compounds.
CF₃CF₂CH═CH₂,
CF₃CF₂CF₂CF₂CH═CH₂ ((perfluorobutyl)ethylene (PFBE)),
CF₃CF₂CF₂CF₂CF═CH₂,
CF₂HCF₂CF₂CF═CH₂,
CF₂HCF₂CF₂CF₂CF═CH₂, and the like.

Specific examples of the monomer (a3) include the following compounds. Among the following, a monomer that is a diene is a monomer capable of undergoing cyclopolymerization.
CF₂═CFOCF₃,
CF₂═CFOCF₂CF₃,
CF₂═CFO(CF₂)₂CF₃ (perfluoro(propyl vinyl ether) (PPVE)),
CF₂═CFOCF₂CF(CF₃)O(CF₂)₂CF₃,
CF₂═CFO(CF₂)₃O(CF₂)₂CF₃,
CF₂═CFO(CF₂CF(CF₃)O)₂(CF₂)₂CF₃,
CF₂═CFOCF₂CF(CF₃)O(CF₂)₂CF₃,
CF₂═CFOCF₂CF═CF₂,
CF₂═CFO(CF₂)₂CF═CF₂, and the like.

Specific examples of the monomer (a4) include the following compounds.
CF₂═CFO(CF₂)₃CO₂CH₃,
CF₂═CFOCF₂CF(CF₃)O(CF₂)₃CO₂CH₃,
CF₂═CFOCF₂CF(CF₃)O(CF₂)₂SO₂F, and the like.

Specific examples of the monomer (a5) include perfluoro(2,2-dimethyl-1,3-dioxole), 2,2,4-trifluoro-5-trifluoromethoxy-1,3-dioxole, and perfluoro(2-methylene-4-methyl-1,3-dioxolane).

Examples of the monomer having no fluorine atoms include the following monomers (b1) to (b4).
Monomer (b1): olefins.
Monomer (b2): vinyl esters.
Monomer (b3): vinyl ethers.
Monomer (b4): an unsaturated acid anhydride.

Specific examples of the monomer (b1) include propylene and isobutene.

Specific examples of the monomer (b2) include vinyl acetate.

Specific examples of the monomer (b3) include ethyl vinyl ether, butyl vinyl ether, cyclohexyl vinyl ether, and hydroxybutyl vinyl ether.

Specific examples of the monomer (b4) include maleic anhydride, itaconic anhydride, citraconic anhydride, and 5-norbomene-2,3-dicarboxylic anhydride.

The third monomer may be used alone or in combination of two or more thereof. As the third monomer, the monomer (a2), HFP, PPVE, and vinyl acetate are preferred, HFP, PPVE, CF₃CF₂CH═CH₂, and PFBE are more preferred, and PFBE is still more preferred, from a viewpoint of easily adjusting the crystallinity and from a viewpoint of an excellent tensile strength and elongation at a high temperature (particularly, at about 180° C.). That is, as the ETFE, a copolymer having a unit based on TFE, a unit based on E, and a unit based on PFBE is preferred.

In the ETFE, a molar ratio of the TFE unit to the E unit (TFE unit/E unit) is preferably 80/20 to 40/60, more preferably 70/30 to 45/55, and still more preferably 65/35 to 50/50. When the TFE unit/E unit is within the above range, heat resistance and a mechanical strength of the ETFE are excellent.

A ratio of the unit based on the third monomer in the ETFE is preferably 0.01 mol % to 20 mol %, more preferably 0.10 mol % to 15 mol %, and still more preferably 0.20 mol % to 10 mol %, with respect to a total (100 mol %) of all units constituting the ETFE. When the ratio of the unit based on the third monomer is within the above range, the heat resistance and the mechanical strength of the ETFE are excellent.

When the unit based on the third monomer includes a PFBE unit, a ratio of the PFBE unit is preferably 0.5 mol % to 4.0 mol %, more preferably 0.7 mol % to 3.6 mol %, and even more preferably 1.0 mol % to 3.6 mol %, with respect to the total (100 mol %) of all units constituting the ETFE. When the ratio of the PFBE unit is within the above range, a tensile elastic modulus of the film at 180° C. can be adjusted within the above range. Further, the tensile strength and elongation at a high temperature, particularly at about 180° C., can be increased.

The substrate may be constituted by the releasable resin alone, or may further contain other components in addition to the releasable resin. Examples of the other components include a lubricant, an antioxidant, an antistatic agent, a plasticizer, and a release agent. The substrate preferably does not contain other components from a viewpoint of preventing staining of a mold.

A thickness of the substrate is preferably 10 μm to 500 μm, more preferably 25 μm to 250 μm, and still more preferably 25 μm to 125 μm. When the thickness of the substrate is equal to or less than an upper limit value of the above range, the film can be easily deformed and has excellent mold conformability. When the thickness of the substrate is equal to or more than a lower limit value of the above range, handling of the film, for example, handling in roll-to-roll, is easy, and wrinkles are less likely to occur even when the film is pulled.

The thickness of the substrate can be measured in accordance with an ISO 4591:1992 (UIS K7130:1999) B1 method: a method for measuring a thickness of a sample taken from a plastic film or sheet by a mass method). Hereinafter, the same applies to a thickness of each layer of the film.

A surface of the substrate may have a surface roughness. An arithmetic average roughness Ra of the surface of the substrate is preferably 0.2 μm to 3.0 μm, and more preferably 0.5 μm to 2.5 μm. When the arithmetic average roughness Ra of the surface of the substrate is equal to or more than a lower limit value of the above range, the releasability is more excellent. When the arithmetic average roughness Ra of the surface of the substrate is equal to or less than an upper limit value of the above range, pinholes are less likely to be formed in the film.

The arithmetic average roughness Ra is measured based on JIS B0601:2013 (ISO 4287:1997, Amd.1:2009). A reference length lr (cutoff value λc) for a roughness curve is 0.8 mm.

In the film of the present disclosure, the O/C is preferably within the range of 0.010 to 0.200 in the surface chemical composition analysis of the substrate on the antistatic layer side by X-ray photoelectron spectroscopy (hereinafter, also referred to as “XPS”). When the O/C is within the above range, the excellent antistatic performance tends to be obtained. The O/C may be 0.030 to 0.150, and may be 0.040 to 0.100.

In the film according to the third embodiment of the present disclosure, the O/C is within the range of 0.010 to 0.200.

In the film of the present disclosure, the N/F is preferably within the range of 0.010 to 0.100 in the surface chemical composition analysis of the substrate on the antistatic layer side by XPS. When the N/F is within the above range, the excellent antistatic performance tends to be obtained. The N/F may be 0.010 to 0.090, and may be 0.010 to 0.080.

In the film according to the fourth embodiment of the present disclosure, the N/F is within the range of 0.010 to 0.100.

In one aspect, it is also preferable to satisfy both any of the above ranges of the O/C and any of the above ranges of the N/F.

XPS is a method of quantifying an amount of an element present on a material surface or the like, and can quantify each element such as carbon (C), oxygen (O), fluorine (F), and nitrogen (N). In measurement of the O/C and the N/F, an object to be analyzed in XPS is set to a depth of 2 nm to 8 nm from a surface of the object to be measured. Information on an analyzer and analysis conditions are as follows.
Analyzer: Quantera PHI manufactured by ULVAC-PHI
X-ray source: Al Kα 14 kV
Beam diameter: 100 μm Φ
Measurement field of view: 800×300 μm²
Measurement mode: narrow spectrum measurement
Measurement elements and measurement area and the number of integrations of binding energy of each element:
   C1s: 278 eV to 297 eV, integration times: 2
   O1s: 525 eV to 544 eV integration times: 3
   N1s: 392 eV to 411 eV, integration times: 8
   F1s: 680 eV to 699 eV, integration times: 1
Pass energy: 224.0 eV
Energy step: 0.4 eV
Number of cycles: 8 cycles
Neutralization gun: use
Angle between a detector and a sample surface: 45°

In the measurement of the N/F and the O/C, target elements in the XPS measurement are four elements, that is, C, O, F, and N, and a ratio (unit: Atomic %) of each of F and N to a total of the four elements is an amount of a corresponding atom. Thereafter, the N/F and the O/C are determined based on each Atomic % value.

A surface of the substrate adjacent to another layer may be subjected to any surface treatment. Examples of the surface treatment include a corona treatment, a plasma treatment, silane coupling agent coating, and adhesive coating. From a viewpoint of adhesion between the substrate and the other layer, a corona treatment or a plasma treatment is preferred.

From a viewpoint of adhesion to a layer adjacent to the substrate, a surface of the substrate on the antistatic layer side is preferably plasma-treated. It has also been found that the antistatic performance of the film tends to be improved by the plasma treatment.

Conditions of the plasma treatment are not particularly limited. In one aspect, the plasma treatment may be performed in a presence of an argon (Ar) gas, an ammonia (NH₃) gas, or a nitrogen (N₂) gas which may or may not be mixed with 10 vol % or less of a hydrogen (H₂) gas.

When the plasma treatment is performed in the presence of the argon gas, a functional group such as a hydroxy group, a carbonyl group, or a carboxy group can be introduced onto the surface of the substrate.

When the plasma treatment is performed in the presence of the ammonia gas, a functional group such as a hydroxy group, a carbonyl group, a carboxy group, an amino group, or an amide group can be introduced onto the surface of the substrate.

When the plasma treatment is performed in the presence of the nitrogen gas, a functional group such as an amino group or an amide can be introduced onto the surface of the substrate. When 10 vol % or less of the hydrogen gas is mixed with the nitrogen gas, a functional group such as an amino group or an amide group can be introduced more efficiently.

Accordingly, the N/F of the surface of the substrate may be adjusted to be within the above range, the O/C of the surface of the substrate may be adjusted to be within the above range, or both the N/F and O/C are adjusted to be within the above ranges.

When the hydrogen gas is mixed with the nitrogen gas, a concentration of the hydrogen gas may be 0.01 vol % to 10 vol %, 1 vol % to 10 vol %, or 1 vol % to 5 vol %.

As for a pressure of an atmosphere in the plasma treatment, it is preferable to use atmospheric pressure (about 760 torr) or a low pressure condition reduced from atmospheric pressure. The lower the pressure, the smaller the power consumption for plasma generation. On the other hand, from a viewpoint of obtaining a sufficient plasma concentration, the pressure is preferably not too low. From the above viewpoints, the pressure of the atmosphere in the plasma treatment may be 0.001 torr to 760 torr, 0.05 torr to 10 torr, or 0.05 torr to 1 torr.

A discharge power in the plasma treatment may be 0.1 kW to 150 kW, 0.5 kW to 120 kW, 1 kW to 100 kW, or 1 kW to 50 kW from a viewpoint of easily introducing an appropriate functional group into the substrate.

In one aspect, the plasma treatment may be performed such that W·t/F (W·sec/(m³/sec)) calculated based on a discharge power (W), a treatment time (t), and a gas flow rate (F) is within a range of 0.3×10¹² to 60.0×10¹², within a range of 0.5×10¹² to 40.0×10¹², or within a range of 1.0×10¹² to 10.0×10¹². When W·t/F is within the above range, an appropriate functional group is easily introduced into the substrate, and better antistatic performance tends to be obtained.

The surface of the substrate may be further subjected to a corona treatment in addition to the plasma treatment, or may be further subjected to a corona treatment before the plasma treatment. It has been found that a strength of the substrate tends to be better when the corona treatment is further performed before the plasma treatment. The reason for the above is not clear, but it is presumed that even if a plasma intensity is relatively increased in the plasma treatment, decomposition of a material on the surface of the substrate can be prevented by performing the corona treatment in advance.

A contact angle of the surface of the substrate on the antistatic layer side is preferably 50° to 100°, and may be 60° to 100°, or may be 70° to 100°. The contact angle is determined by a contact angle meter (for example, contact angle meter DMs-401 manufactured by Kyowa Interface Science Co., Ltd.).

The substrate may be a single layer or may have a multilayer structure. Examples of the multilayer structure include a structure in which a plurality of layers each containing a releasable resin are laminated. In this case, the releasable resins contained in each of the plurality of layers may be the same as or different from each other. From viewpoints of shape conformability along inner surface of mold chase, a tensile elongation, a manufacturing cost, and the like, the substrate is preferably a single layer.

<Antistatic Layer>

The antistatic layer is not particularly limited as long as the antistatic layer is a layer having an antistatic function. The antistatic layer may be provided on the substrate in a manner adjacent to the substrate, or may be provided on the substrate via at least a third layer adjacent to the substrate.

The antistatic layer may contain an antistatic agent. Examples of the antistatic agent include an ionic liquid, a conductive polymer, a metal ion-conducting salt, and a conductive metal oxide. The antistatic agent may be used alone or in combination of two or more thereof.

The conductive polymer is a polymer in which electrons move and diffuse along a skeleton of the polymer. Examples of the conductive polymer include a polyaniline-based polymer, a polyacetylene-based polymer, a polyparaphenylene-based polymer, a polypyrrole-based polymer, a polythiophene-based polymer, and a polyvinylcarbazole-based polymer.

Examples of the metal ion-conducting salt include a lithium salt compound.

Examples of the conductive metal oxide include tin oxide, tin-doped indium oxide, antimony-doped tin oxide, phosphorus-doped tin oxide, zinc antimonate, and antimony oxide.

The antistatic agent is preferably at least one selected from the group consisting of a polyaniline polymer, a polyacetylene polymer, a polyparaphenylene polymer, a polypyrrole polymer, a polythiophene polymer, and a polyvinylcarbazole polymer from a viewpoint of excellent heat resistance and conductivity.

The antistatic agent is preferably dispersed in a resin binder. That is, the antistatic layer is preferably a layer in which an antistatic agent is dispersed in a resin binder.

The resin binder preferably has heat resistance. For example, when the film is used in an encapsulating step of a semiconductor, the resin binder preferably has heat resistance at about 180° C. From a viewpoint of excellent heat resistance, the resin binder preferably contains at least one selected from the group consisting of an acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer. Among these, from a viewpoint of an excellent mechanical strength, it is preferable to contain at least one (for example, only an acrylic resin) selected from the group consisting of an acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer. Further, from a viewpoint of excellent heat resistance and dispersibility of the antistatic agent, a polyester resin and an acrylic resin are preferred.

In the antistatic layer, the resin binder may be crosslinked. When the resin binder is crosslinked, the heat resistance is excellent as compared with a case where the resin binder is not crosslinked.

A content of the antistatic agent in the antistatic layer is preferably such an amount that a surface resistance value of the film is within a range to be described later, from a viewpoint of sufficiently exhibiting an antistatic function.

In one aspect, when the antistatic layer is the layer in which the antistatic agent is dispersed in the resin binder, a content of the antistatic agent may be 3 mass % to 50 mass % or may be 5 mass % to 20 mass % with respect to the resin binder. When the content of the antistatic agent is equal to or more than a lower limit value of the above range, the surface resistance value of the film is easy to be within a suitable range. When the content of the antistatic agent is equal to or less than an upper limit value of the above range, the adhesion of the antistatic layer is easy to be good.

The antistatic layer may contain an additive other than the antistatic agent. Examples of the additive include a lubricant, a coloring agent, and a coupling agent.

Examples of the lubricant include microbeads made of a thermoplastic resin, fumed silica, and polytetrafluoroethylene (PTFE) fine particles.

Examples of the coloring agent include various organic coloring agents and inorganic coloring agents, and more specifically, cobalt blue, red iron oxide, and cyanine blue.

Examples of the coupling agent include a silane coupling agent and a titanate coupling agent.

A thickness of the antistatic layer is preferably 0.05 μm to 3.0 μm, and more preferably 0.1 μm to 2.5 μm. When the thickness of the antistatic layer is equal to or more than a lower limit value of the above range, conductivity is exhibited and an antistatic function is excellent. When the thickness of the antistatic layer is equal to or less than an upper limit value of the above range, production process stability including an appearance of a coated surface is excellent.

<Other Layers>

In the present disclosure, the film may or may not include other layers as long as the film includes the substrate and the antistatic layer. Examples of the other layers include an adhesive layer, a base layer, a gas barrier layer, and a colored layer. These layers may be used alone or in combination of two or more thereof.

Examples of a layer structure of the film are shown below. The layer structure of the film of the present disclosure is not limited to the following.
(1) A film including a substrate and an antistatic layer in this order.
(2) A film including a substrate, an antistatic layer, and an adhesive layer in this order.
(3) The film according to any one of the above (1) and (2), further including a gas barrier layer, a colored layer, and the like at any position closer to the antistatic layer side than the substrate.

-Adhesive Layer-

The film may further include the adhesive layer. The adhesive layer is a layer having adhesiveness to other members. A material of the adhesive layer is not particularly limited. In one aspect, the adhesive layer may contain a reaction cured product of a hydroxy group-containing (meth)acrylic polymer and a polyfunctional isocyanate compound. In this case, the hydroxy group-containing (meth)acrylic polymer reacts with the polyfunctional isocyanate compound to crosslink and form the reaction cured product. The adhesive layer may be a reaction cured product of a hydroxy group-containing (meth)acrylic polymer, a polyfunctional isocyanate compound, and other components.

The hydroxy group-containing (meth)acrylic polymer may be a copolymer having at least a hydroxy group-containing (meth)acrylate unit and a unit different from the hydroxy group-containing (meth)acrylate unit.

Examples of a monomer forming the hydroxy group-containing (meth)acrylate unit include 2-hydroxyethyl (meth)acrylate, 2-hydroxypropyl (meth)acrylate, 4-hydroxybutyl (meth)acrylate, 1,4-cyclohexanedimethanol monoacrylate, and 2-acryloyloxyethyl-2-hydroxyethyl-phthalic acid. The monomer forming the hydroxy group-containing (meth)acrylate unit may be used alone or in combination of two or more thereof.

Examples of a monomer forming the unit different from the hydroxy group-containing (meth)acrylate unit include a (meth)acrylate having no hydroxy groups, (meth) acrylic acid, acrylonitrile, and a macromer having an unsaturated double bond.

Examples of the (meth)acrylate having no hydroxy groups include alkyl (meth)acrylate, cyclohexyl (meth)acrylate, phenyl (meth)acrylate, toluyl (meth)acrylate, benzyl (meth)acrylate, 2-methoxyethyl (meth)acrylate, 3-methoxybutyl (meth)acrylate, glycidyl (meth)acrylate, 2-aminoethyl (meth)acrylate, 3-(methacryloyloxypropyl)trimethoxysilane, trifluoromethylmethyl (meth)acrylate, 2-trifluoromethylethyl (meth)acrylate, 2-perfluoroethylethyl (meth)acrylate, 2-perfluoroethyl-2-perfluorobutylethyl (meth)acrylate, 2-perfluoroethyl (meth)acrylate, perfluoromethyl (meth)acrylate, diperfluoromethylmethyl (meth)acrylate, 2-perfluoromethyl-2-perfluoroethylmethyl (meth)acrylate, 2-perfluorohexylethyl (meth)acrylate, 2-perfluorodecylethyl (meth)acrylate, and 2-perfluorohexadecylethyl (meth)acrylate.

The alkyl (meth)acrylate is preferably a compound whose alkyl group has 1 to 12 carbon atoms. Examples thereof include methyl (meth)acrylate, ethyl (meth)acrylate, butyl (meth)acrylate, 2-ethylhexyl (meth)acrylate, n-propyl (meth)acrylate, isopropyl (meth)acrylate, isobutyl (meth)acrylate, t-butyl (meth)acrylate, n-pentyl (meth)acrylate, n-hexyl (meth)acrylate, n-heptyl (meth)acrylate, n-octyl (meth)acrylate, nonyl (meth)acrylate, decyl (meth)acrylate, and dodecyl (meth)acrylate.

Examples of the macromer having an unsaturated double bond include a macromer having a polyoxyalkylene chain such as a (meth)acrylate of a polyethylene glycol monoalkyl ether.

A hydroxy group contained in the hydroxy group-containing (meth)acrylic polymer is a crosslinkable functional group that reacts with an isocyanate group in the polyfunctional isocyanate compound.

A hydroxy value of the hydroxy group-containing (meth)acrylic polymer is preferably 1 mgKOH/g to 100 mgKOH/g, and more preferably 29 mgKOH/g to 100 mgKOH/g. The hydroxy value is measured by a method defined in JIS K0070:1992.

The hydroxy group-containing (meth)acrylic polymer may or may not have a carboxy group. Similar to the hydroxy group, the carboxy group is a crosslinkable functional group that reacts with the isocyanate group in the polyfunctional isocyanate compound.

An acid value of the hydroxy group-containing (meth)acrylic polymer is preferably 0 mgKOH/g to 100 mgKOH/g, and more preferably 0 mgKOH/g to 30 mgKOH/g. Similar to the hydroxy value, the acid value is measured by the method defined in JIS K0070:1992.

The polyfunctional isocyanate compound is a compound having 2 or more isocyanate groups, and is preferably a compound having 3 to 10 isocyanate groups.

Examples of the polyfunctional isocyanate compound include hexamethylene diisocyanate (HDI), tolylene diisocyanate (TDI), diphenylmethane diisocyanate (MDI), naphthalene diisocyanate (NDI), tolidine diisocyanate (TODI), isophorone diisocyanate (IPDI), xylylene diisocyanate (XDI), triphenylmethane triisocyanate, and tris(isocyanatophenyl)thiophosphate. Examples thereof include isocyanurates (trimers) and biurets of the polyfunctional isocyanate compounds, and adducts of the polyfunctional isocyanate compounds and polyol compounds.

The polyfunctional isocyanate compound preferably has an isocyanurate ring from a viewpoint that the reaction cured product (adhesive layer) exhibits a high elastic modulus due to flatness of the ring structure.

Examples of the polyfunctional isocyanate compound having an isocyanurate ring include an isocyanurate of HDI (isocyanurate type HDI), an isocyanurate of TDI (isocyanurate type TDI), and an isocyanurate of MDI (isocyanurate type MDI).

When the adhesive layer is a reaction cured product of an adhesive layer composition containing a hydroxy group-containing acrylic-based polymer and a polyfunctional isocyanate compound, contents of the hydroxy group-containing acrylic-based polymer and the polyfunctional isocyanate compound in the adhesive layer composition are preferably set such that M_{COOH}/(M_{NCO}−M_{OH}) is 0 to 1.0, and M_{NCO}/(M_{COOH}+M_{OH}) is 0.4 to 3.5. Here, M_{OH} is the number of moles of hydroxy groups derived from the hydroxy group-containing acrylic-based polymer, M_{COOH} is the number of moles of carboxy groups derived from the hydroxy group-containing acrylic-based polymer, and M_{NCO} is the number of moles of isocyanate groups derived from the polyfunctional isocyanate compound.

M_{COOH}(M_{NCO}-M_{OH}) is preferably 0 to 1.0, and more preferably 0 to 0.5. When M_{COOH}/(M_{NCO}-M_{OH}) is equal to or more than a lower limit value of the above range, adhesion to a member to be in contact is excellent. When M_{COOH}/(M_{NCO}-M_{OH}) is equal to or less than an upper limit value of the above range, the number of free carboxy groups remaining in the adhesive layer is reduced, and thus peelability from the member to be in contact is excellent.

M_{NCO}(M_{COOH}+M_{OH}) is preferably 0.4 to 3.5, and more preferably 0.4 to 3.0. When M_{NCO}/(M_{COOH}+M_{OH}) is equal to or more than a lower limit value of the above range, a crosslinking density and an elastic modulus of the adhesive layer are increased, and the releasability and the peelability from the member to be in contact are excellent. When M_{NCO}/(M_{COOH}+M_{OH}) is equal to or less than an upper limit value of the above range, the elastic modulus of the adhesive layer does not become too high, and the adhesion to the member to be in contact is excellent.

A total content of the hydroxy group-containing acrylic-based polymer and the polyfunctional isocyanate compound in the adhesive layer composition is preferably 50 mass % or more with respect to a total amount of the adhesive layer composition.

The adhesive layer may contain components such as a crosslinking catalyst (amines, a metal compound, an acid, and the like), a reinforcing filler, a coloring dye, a pigment, and an antistatic agent.

A thickness of the adhesive layer is preferably 0.05 μm to 3.0 μm, more preferably 0.05 μm to 2.5 μm, and still more preferably 0.05 μm to 2.0 μm. When the thickness of the adhesive layer is equal to or more than a lower limit value of the above range, the releasability is excellent. When the thickness of the adhesive layer is equal to or less than an upper limit value of the above range, coating stability is excellent. When the thickness of the adhesive layer is equal to or less than the upper limit value of the above range, a tack after coating does not become too strong, and a continuous coating process becomes easy.

A suitable example of the adhesive layer is an adhesive layer described in WO2016/125796.

[Method for Manufacturing Film]

The film can be produced, for example, by applying an antistatic layer coating liquid on one surface of a substrate and drying the coating liquid. In addition, a desired layer other than the antistatic layer, such as an adhesive layer or a base layer, may be further formed by coating. In the formation of each layer, heating may be performed to promote curing.

In one aspect, a method for manufacturing a film may include: plasma-treating a surface of a substrate; and providing an antistatic layer on the plasma-treated substrate or providing an antistatic layer on the plasma-treated substrate via at least a third layer adjacent to the substrate, in which in the surface chemical composition analysis of the substrate after the plasma treatment on an antistatic layer side by XPS, O/C may be within a range of 0.010 to 0.200, N/F may be within a range of 0.010 to 0.100, or both ranges of O/C and N/F may be satisfied. In this aspect, an adhesive layer may be further provided on a surface of the antistatic layer opposite to the substrate.

The plasma treatment may be performed in a presence of an argon gas, an ammonia gas, or a nitrogen gas which may or may not be mixed with 10 vol % or less of a hydrogen gas.

Further, the method for manufacturing a film may further include corona-treating the surface of the substrate in addition to the plasma treatment, or may further include corona-treating the surface of the substrate before the plasma treatment.

Details of the plasma treatment and the corona treatment in this aspect are as described above.

[Characteristics of Film]

(Adhesion of Antistatic Layer)

In the film of the present disclosure, it is considered that the antistatic layer has the excellent adhesion, and as a result, the excellent antistatic performance is obtained. In one aspect, the following tape peeling test is used as an index of the adhesion.

After 300% uniaxial stretching at 25° C., Cellotape® is pressure-bonded to a surface of a film on an antistatic layer side using a roller through 5 reciprocations with a load of 4 kg, and the Cellotape® is peeled off at a speed of 100 m/min in a direction of 180° with respect to the film within 5 minutes to obtain a ratio of a peeled area of the film to an area of an adhesive portion of the Cellotape®. Specifically, the tape peeling test can be performed by a method described in Examples.

The ratio of the peeled area is preferably less than 5%, more preferably 4% or less, still more preferably 3% or less, and may be 0%. In the first embodiment of the present disclosure, the ratio of the peeled area is less than 5%.

A stretching speed of the uniaxial stretching is not particularly defined. The uniaxial stretching may be stretching under a constant load or may be stretching at a constant speed. In a case of the stretching at a constant speed, when an initial length of a stretched portion is Lm, the stretching is preferably performed at a speed within a range of 0.0005×Lm/min to 10×Lm/min, and more preferably at a speed within a range of 0.001×Lm/min to 10×Lm/min. In a case of the stretching under a constant load, a rectangular film may be stretched to 300% by a method such as fixing one side of the rectangular film to an upper portion and hanging a weight not exceeding a breaking strength from the other side, that is, by creep deformation. When a phenomenon such as a film breakage occurs during the uniaxial stretching, stretching conditions are examined to stretch the film to 300%.

In another aspect, the following wiping test is used as an index of the adhesion. Although the embodiments of the present disclosure are not limited by any means, the wiping test is a test under a condition which is relatively stricter than that of the tape peeling test.

After 300% uniaxial stretching at 25° C., a film is wiped by rubbing a surface of the film on an antistatic layer side using a nonwoven fabric (for example, Bemcot (registered trademark)) to which acetone is attached through 20 reciprocations with a load of 4 kg. Hazes before and after the wiping are measured at the same position of the film, a haze before the wiping is denoted by H1, and a haze after the wiping is denoted by H2. When a relation of (H2-H1)≥0 is satisfied, it can be determined that peeling does not occur after the wiping and good adhesion is obtained. Specifically, the wiping test can be performed by a method described in Examples. In the second embodiment of the present disclosure, the relation of (H2-H1)≥0 is satisfied. A case where the relation of (H2-H1)≥1 is satisfied is preferred, and a case where the relation of (H2-H1)≥3 is satisfied is more preferred. An upper limit value of (H2-H1) is not particularly limited, but from a viewpoint of avoiding erroneous evaluation due to an unexpected film scratch, evaluation is preferably performed within a range that satisfies the relation of (H2-H1)≤40, and is more preferably performed within a range that satisfies the relation of (H2-H1)≤30.

The same conditions as in the tape peeling test can be applied to conditions for the uniaxial stretching.

(Tensile Strength)

A tensile strength of the film is preferably 35 MPa or more, more preferably 40 MPa or more, still more preferably 45 MPa or more, and particularly preferably 50 MPa or more. The tensile strength of the film is not particularly limited, and is preferably as large as possible.

The tensile strength of the film is measured in accordance with JIS K7127:1999. Specifically, the measurement is performed by a method described in Examples.

(Surface Resistance Value)

The surface resistance value of the film is not particularly limited, and may be 10¹⁷ Ω/□ or less, preferably 10¹¹ Ω/□ or less, more preferably 10¹⁰ Ω/□ or less, and still more preferably 10⁹ Ω/□ or less. A lower limit of the surface resistance value is not particularly limited.

The surface resistance value of the film is measured according to IEC 60093:1980: double ring electrode method at an applied voltage of 500 V for an application time of 1 minute. As a measurement device, for example, an ultra-high resistance meter R8340 (Advantec) can be used.

[Use of Film]

Use of the film of the present disclosure is not particularly limited. For example, the film of the present disclosure is useful as a release film used in a step of encapsulating a semiconductor device with a curable resin. In addition, the film of the present disclosure has the excellent antistatic performance even when stretched, and thus is also useful as a release film used in a step of producing a semiconductor package having a complicated shape, for example, an encapsulated body in which a part of an electronic component is exposed from an encapsulating resin.

<<Method for Manufacturing Semiconductor Package>>

In one aspect, a method for manufacturing a semiconductor package includes: disposing the film of the present disclosure on an inner surface of a mold; disposing a board including a semiconductor device in the mold in which the film is disposed; encapsulating a semiconductor device in the mold with a curable resin to produce an encapsulated body; and releasing the encapsulated body from the mold.

Examples of the semiconductor package include: an integrated circuit in which semiconductor devices such as a transistor and a diode are integrated; and a light-emitting diode including a light-emitting device.

A package shape of the integrated circuit may cover the entire integrated circuit, or may cover a part of the integrated circuit, that is, may expose a part of the integrated circuit. Specific examples include a ball grid array (BGA), a quad flat non-leaded package (QFN), and a small outline non-leaded package (SON).

From a viewpoint of productivity, the semiconductor package is preferably manufactured through collective encapsulating and singulation, and examples thereof include an integrated circuit whose encapsulating method is a moldied array packaging (MAP) method or a wafer lebel packaging (WL) method.

The curable resin is preferably a thermosetting resin such as an epoxy resin or a silicone resin, and more preferably an epoxy resin.

In one aspect, the semiconductor package may or may not include an electronic component such as a source electrode or a seal glass in addition to the semiconductor device. A part of the semiconductor device and the electronic component such as a source electrode or a seal glass may be exposed from the resin.

As a method for manufacturing the semiconductor package, a known manufacturing method can be adopted except that the film of the present disclosure is used. For example, a transfer molding method may be used as a method for encapsulating the semiconductor device, and a known transfer molding device may be used as a device used in this case. Manufacturing conditions can also be the same as those in the known method for manufacturing a semiconductor package.

### EXAMPLES

Next, the embodiments of the present disclosure will be specifically described with reference to Examples, but the embodiments of the present disclosure are not limited to these Examples. In the following Examples, Examples 1 to 6, 13 to 15, and 18 to 23 are Working Examples, and Examples 7 to 12, 16, and 17 are Comparative Examples.

Materials used for forming each layer are as follows.

-Substrate-
ETFE film 1: Fluon (registered trademark) ETFE LM720AXP (manufactured by AGC Inc.) was fed to an extruder equipped with a T-die, and taken up between a pressing roll with an uneven surface and a metal roll with a mirror surface to form a film having a thickness of 50 μm. A temperature of the extruder and the T-die was 300° C., and a temperature of the pressing roll and the metal roll was 90° C. Ra of a surface of the obtained film was 2.2 μm on a pressing roll side and 0.1 μm on a mirror surface side.

-Antistatic Layer Coating Liquid-
Antistatic agent-containing material 1: ARACOAT (registered trademark) AS601D (manufactured by Arakawa Chemical Industries, Ltd.), solid content: 3.4 mass %, a conductive polythiophene: 0.4 mass %, and an acrylic resin: 3.0 mass %.
Curing agent 1: ARACOAT (registered trademark) CL910 (manufactured by Arakawa Chemical Industries, Ltd.), solid content: 10 mass %, and a polyfunctional aziridine compound.

-Adhesive Layer Coating Liquid-
(Meth)acrylic polymer 1: Nissetsu (registered trademark) KP2562 (manufactured by Nippon Carbide Industries Co., Inc.), containing a hydroxy group, not containing a carboxy group.
Polyfunctional isocyanate compound 1: Nissetsu CK157 (manufactured by Nippon Carbide Industries Co., Inc.), solid content: 100%, isocyanurate type hexamethylene diisocyanate, NCO content: 21 mass %.
Catalyst dilution solution 1: Nissetsu CK-920 (manufactured by Nippon Carbide Industries Co., Inc.), acetylacetone dilution solution of dioctyltin dilaurate, tin content: 0.05%.

A film was produced by the following procedures.

<Pretreatment of Substrate>

In the corresponding Examples described in Tables 1 and 2, a surface of an ETFE film was subjected to a plasma treatment and, if necessary, a corona treatment under conditions described in Tables 1 and 2.

(Measurement of O/C and N/F)

O/C and N/F analysis was performed by XPS on a substrate that was pretreated as necessary. An object to be analyzed in XPS was set to a depth of 2 nm to 8 nm from a surface of the substrate. Information on an analyzer and analysis conditions are as follows.
Analyzer: Quantera PHI manufactured by ULVAC-PHI
X-ray source: Al Kα 14 kV
Beam diameter: 100 μm Φ
Measurement field of view: 800×300 μm²
Measurement mode: narrow spectrum measurement
Measurement elements and measurement area and the number of integrations of binding energy of each element:
   C1s: 278 eV to 297 eV, integration times: 2
   O1s: 525 eV to 544 eV, integration times: 3
   N1s: 392 eV to 411 eV, integration times: 8
   F1s: 680 eV to 699 eV, integration times: 1
Pass energy: 224.0 eV
Energy step: 0.4 eV
Number of cycles: 8 cycles
Neutralization gun: use
Angle between a detector and a sample surface: 45°

Target elements in the XPS measurement are four elements, that is, C, O, F, and N, and a ratio (unit: Atomic %) of each of F and N to a total of the four elements is an amount of a corresponding atom. Thereafter, the O/C and the N/F were determined based on each Atomic % value.

[Production of Antistatic Layer]

An antistatic layer coating liquid having a solid content of 2 mass % was prepared by mixing 100 parts by mass of the antistatic agent-containing material 1 and 10 parts by mass of the curing agent 1. The surface of the substrate was coated with the antistatic layer coating liquid using a gravure coater and dried to form an antistatic layer having a thickness of 0.2 μm. The coating was performed by a direct gravure method using a roll with grating 150 # of 100 mm diameter×250 mm width-depth of 40 μm as a gravure plate. The drying was performed at 55° C. for 1 minute through a roll-support drying oven with an air volume of 19 m/sec.

<Production of Adhesive Layer>

An adhesive layer coating liquid was prepared by mixing 100 parts by mass of the (meth)acrylic polymer 1, 6 parts by mass of the polyfunctional isocyanate compound 1, 21 parts by mass of the catalyst dilution solution 1, and ethyl acetate. A blending amount of the ethyl acetate was set such that a solid content of the adhesive layer coating liquid was 14 mass %.

A surface of the antistatic layer was coated with the adhesive layer coating liquid using a gravure coater and dried to form an adhesive layer having a thickness of 0.8 μm. The coating was performed by a direct gravure method using a roll with grating 150 # of 100 mm diameter×250 mm width-depth of 40 μm as a gravure plate. The drying was performed at 65° C. for 1 minute through a roll-support drying oven with an air volume of 19 m/sec. Next, curing was performed at 40° C. for 48 hours to obtain a film.

<Tape Peeling Test>

Taking machine direction (MD) of a film as a longitudinal direction, the film was cut into a shape of length 150 mm×width 50 mm. Next, a preliminary strain was applied using a universal testing machine, that is, autograph AGC-X manufactured by Shimadzu Corporation. First, a sample gripping jig having a chuck width of 50 mm was mounted, a distance between chucks was set to 50 mm, both sides of the film cut out previously were evenly clamped by chuck jigs, and a sample was mounted without wrinkles. Thereafter, in an environment of 25° C., the chuck was moved at a displacement of 150 mm at a speed of 50 mm/min to apply a uniaxial stretching strain to the film (that is, 300% stretching). Within 10 seconds after the stretching, the chuck was removed and the sample was allowed to stand for 15 minutes.

A nichiban cellophane adhesive tape “Cellotape®” CT-18 (width: 18 mm) was directly pasted with a length of 70 mm in one axial direction stretched previously, and was pressure-bonded using a plastic roller having a diameter of 35 mm and a width of 40 mm through 5 reciprocations with a load of 4 kg. Thereafter, within 5 minutes, an end of the adhered tape was held and peeled off at a speed of 100 m/min in a direction of 180° with respect to the film. A time required for the peeling was about 0.4 seconds.

Thereafter, the presence or absence of deposits on an adhesive surface of the tape and the presence or absence of peeling of a coating film on a film side were visually evaluated. A film having peeling defects of 5% or more of an area of a surface of the film was evaluated as “Peeling present”, and a film having peeling defects of less than 5% was evaluated as “Peeling absent”.

[Wiping Test]

Taking machine direction (MD) of a film as a longitudinal direction, the film was cut into a shape of length 150 mm×width 50 mm. Next, a preliminary strain was applied using a universal testing machine, that is, autograph AGC-X manufactured by Shimadzu Corporation. First, a sample gripping jig having a chuck width of 50 mm was mounted, a distance between chucks was set to 50 mm, both sides of the film cut out previously were evenly clamped by chuck jigs, and a sample was mounted without wrinkles. Thereafter, in an environment of 25° C., the chuck was moved at a displacement of 150 mm at a speed of 50 mm/min to apply a uniaxial stretching strain to the film (that is, 300% stretching). Within 10 seconds after the stretching, the chuck was removed and the sample was allowed to stand for 15 minutes.

Next, a haze was measured by optical measurement at a place where the stretching strain was applied. A haze H1 of a stretched portion was determined using a haze meter NDH5000 manufactured by Nippon Denshoku Industries Co., Ltd.

Next, Bemcot (registered trademark) M-311 (one piece, a nonwoven fabric having 1.6 g, 23 cm×24 cm, a basis weight of 28.9 g/m²) manufactured by Asahi Kasei Corporation, was folded in quarter and impregnated with 10 g of acetone, and a surface of a coating film of the film was rubbed through 20 reciprocations while pressing the acetone-attached nonwoven fabric with one finger with a load of 4 kg. Thereafter, the acetone attached to the film was dried in an environment of 25° C. for 15 minutes, and then a haze of the same portion as that measured before the wiping was measured to determine a haze H2.

When a haze change value satisfied (H2-H1)≥0, the coating film sufficiently remained on a surface of a substrate, and it was determined as “Peeling absent”. When the haze change value satisfied (H2-H1)<0, it was determined as “Peeling present”.

[Adhesion Rank]

Based on results of the tape peeling test and the wiping test, an adhesion rank of a coating film of the film produced in each example was set as follows.
A. No peeling was observed in the tape peeling test and the wiping test.
B: No peeling was observed in the tape peeling test, but peeling was observed in the wiping test.
C: Peeling was observed in the tape peeling test and the wiping test.

[Withstand Voltage Measurement]

A semiconductor device of 5 mm×5 mm×200 μm thick fixed to a copper lead frame of 70 mm×230 mm was encapsulated using an encapsulating device (transfer molding device G-LINE Manual System, manufactured by APIC YAMADA CORPORATION). As an encapsulating resin, an epoxy resin composition to be described later was used. Before the encapsulating step, a roll of a film having a width of 190 mm was set in a roll-to-roll manner in an upper mold having a depth of 250 μm. After the lead frame with the semiconductor device fixed was disposed in a lower mold, the film was vacuum-sucked onto the upper mold, the mold was clamped, and the curable resin was poured into the mold. After a pressure was applied at 175° C. for 5 minutes, the mold was opened and an encapsulated body was taken out.

The epoxy resin composition was obtained by pulverizing and mixing the following components with a super mixer for 5 minutes. A cured product of the epoxy resin composition had a glass transition temperature of 135° C., a storage elastic modulus of 6 GPa at 130° C., and a storage elastic modulus of 1 GPa at 180° C.
Phenylene skeleton-containing phenol aralkyl-type epoxy resin (softening point: 58° C., epoxy equivalent: 277 g/eq): 8 parts by mass
Bisphenol A-type epoxy resin (melting point: 45° C., epoxy equivalent: 172 g/eq): 2 parts by mass
Phenylene skeleton-containing phenol aralkyl resin (softening point: 65° C., hydroxy equivalent: 165 g/eq): 2 parts by mass
Phenol novolac resin (softening point: 80° C., hydroxy equivalent: 105 g/eq): 2 parts by mass
Curing accelerator (triphenylphosphine): 0.2 parts by mass
Inorganic filler (fused spherical silica with a median diameter of 16 μm): 84 parts by mass
Carnauba wax: 0.1 parts by mass
Carbon black: 0.3 parts by mass
Coupling agent (3-glycidoxypropyltrimethoxysilane): 0.2 parts by mass

Using a sphere-plane electrode described in JIS K6911:2006, a spherical electrode was brought into contact with a place where the encapsulated semiconductor device was present, a low-speed boost test was performed, and a withstand voltage was measured at a boost speed of 100 V/S. The test was performed in atmosphere. A sphere with a diameter of 6 mm and a flat plate with a cylinder shape having diameter of 6 mm were used. A 100 kV dielectric breakdown tester YST-243-100RHO (Yamayo shikenki) was used for the measurement.

A case where the withstand voltage was 1.0 kV or more was determined as good (A), and a case where the withstand voltage was less than 1.0 kV was determined as poor (C).

[Measurement of Tensile Strength]

A tensile test was performed at 25° C. at a chuck speed of 100 mm/min using a type V dumbbell according to JIS K7127:1999. A breaking force at that time was measured and converted to a stress based on an initial sample cross-sectional area.

TABLE 1

| Item | | Unit | Ex. 1 | Ex. 2 | Ex. 3 | Ex. 4 | Ex. 5 | Ex. 6 |
|---|---|---|---|---|---|---|---|---|
| Corona treatment of substrate | | — | — | — | — | — | present | present |
| Plasma | Treatment | — | N₂/H₂ (3%) | N₂/H₂ (3%) | N₂/H₂ (3%) | N₂/H₂ (3%) | N₂/H₂ (3%) | N₂/H₂ (3%) |
| treatment | environment | | | | | | | |
| conditions of | Pressure | torr | 0.1 | 0.1 | 0.1 | 0.1 | 0.1 | 0.1 |
| substrate | Power | kW | 3 | 3 | 3 | 3 | 3 | 32 |
| | Treatment speed | m/min | 1 | 0.5 | 2 | 0.1 | 1 | 1 |
| | Treatment time | sec | 43 | 86 | 22 | 431 | 43 | 43 |
| | Wt/F | W · sec/ | 3.0 × 10¹² | 6.1 × 10¹² | 1.5 × 10¹² | 30.3 × 10¹² | 3.0 × 10¹² | 36.6 × 10¹² |
| | | (m³/sec) | | | | | | |
| Characteristic | Contact angle | ° | 92 | 81 | 97 | 54 | 87 | 50 |
| of substrate | O/C | — | 0.046 | 0.070 | 0.030 | 0.110 | 0.080 | 0.140 |
| surface | N/F | — | 0.012 | 0.024 | 0.006 | 0.070 | 0.017 | 0.090 |
| Tape peeling | Presence or | — | Peeling | Peeling | Peeling | Peeling | Peeling | Peeling |
| test | absence of | | absent | absent | absent | absent | absent | absent |
| | peeling | | | | | | | |
| Wiping test | H2 − H1 | % | 6 | 8 | 2 | 2 | 6 | 2 |
| | Peeling | — | Peeling | Peeling | Peeling | Peeling | Peeling | Peeling |
| | determination | | absent | absent | absent | absent | absent | absent |
| Adhesion rank | | — | A | A | A | A | A | A |
| Withstand | Encapsulation | μm | 46 | 48 | 46 | 47 | 48 | 47 |
| voltage test | thickness | | | | | | | |
| | Average | kV | 1.7 | 1.7 | 1.5 | 1.6 | 1.7 | 1.7 |
| | withstand | | | | | | | |
| | voltage | | | | | | | |
| | Withstand | — | A | A | A | A | A | A |
| | voltage | | | | | | | |
| | performance | | | | | | | |
| Tensile strength | | MPa | 54 | 55 | 56 | 50 | 56 | 53 |
| Item | | Unit | Ex. 7 | Ex. 8 | Ex. 9 | Ex. 10 | Ex. 11 | Ex. 12 |
| Corona treatment of substrate | | — | present | — | — | — | — | — |
| Plasma | Treatment | — | N₂/H₂ (3%) | — | N₂/H₂ (3%) | N₂/H₂ (3%) | N₂/H₂ (3%) | N₂/H₂ (3%) |
| treatment | environment | | | | | | | |
| conditions of | Pressure | torr | 0.1 | — | 0.1 | 0.1 | 0.1 | 0.1 |
| substrate | Power | kW | 170 | — | 0.03 | 3 | 96 | 3 |
| | Treatment | m/min | 1 | — | 1 | 15 | 1 | 0.075 |
| | speed | | | | | | | |
| | Treatment time | sec | 43 | — | 43 | 3 | 43 | 575 |
| | Wt/F | W · sec/ | 193.9 × 10¹² | — | 0.0 × 10¹² | 0.2 × 10¹² | 109.1 × 10¹² | 40.4 × 10¹² |
| | | (m³/sec) | | | | | | |
| Characteristic | Contact angle | ° | 45 | 103 | 102 | 102 | 46 | 44 |
| of substrate | O/C | — | 0.500 | 0.000 | 0.006 | 0.004 | 0.500 | 0.500 |
| surface | N/F | — | 0.136 | 0.000 | 0.001 | 0.001 | 0.110 | 0.160 |
| Tape peeling | Presence or | — | Peeling | Peeling | Peeling | Peeling | Peeling | Peeling |
| test | absence of | | present | present | present | present | present | present |
| | peeling | | | | | | | |
| Wiping test | H2 − H1 | % | −23 | −23 | −23 | −23 | −23 | −23 |
| | Peeling | — | Peeling | Peeling | Peeling | Peeling | Peeling | Peeling |
| | determination | | present | present | present | present | present | present |
| Adhesion rank | | — | C | C | C | C | C | C |
| Withstand | Encapsulation | μm | 48 | 47 | 47 | 47 | 48 | 47 |
| voltage test | thickness | | | | | | | |
| | Average | kV | 0.3 | 0.1 | 0.1 | 0.3 | 0.5 | 0.1 |
| | withstand | | | | | | | |
| | voltage | | | | | | | |
| | Withstand | — | C | C | C | C | C | C |
| | voltage | | | | | | | |
| | performance | | | | | | | |

| | | | | | | | |
|---|---|---|---|---|---|---|---|
| Tensile strength | MPa | 45 | 57 | 57 | 57 | 46 | 57 |

TABLE 2

| Item | | Unit | Ex. 13 | Ex. 14 | Ex. 15 | Ex. 16 | Ex. 17 | Ex. 18 |
|---|---|---|---|---|---|---|---|---|
| Corona treatment of substrate | | — | — | — | — | — | — | — |
| Plasma treatment | Treatment | — | Ar | Ar | Ar | Ar | Ar | N₂/H₂ (3%) |
| conditions of | environment | | | | | | | |
| substrate | Pressure | torr | 0.1 | 0.1 | 0.1 | 0.1 | 0.1 | 752 |
| | Power | kW | 3 | 11 | 3 | 0.03 | 66 | 32 |
| | Treatment speed | m/min | 1 | 1 | 3 | 1 | 1 | 1 |
| | Treatment time | sec | 43 | 43 | 14 | 43 | 43 | 43 |
| | Wt/F | W · sec/ | 3.0 × 10¹² | 12.1 × 10¹² | 1.0 × 10¹² | 0.0 × 10¹² | 75.8 × 10¹² | 36.6 × 10¹² |
| | | (m³/sec) | | | | | | |
| Characteristic of | Contact angle | ° | 86 | 77 | 97 | 102 | 33 | 92 |
| substrate surface | O/C | — | 0.050 | 0.080 | 0.020 | 0.007 | 0.500 | 0.050 |
| | N/F | — | 0 | 0 | 0 | 0 | 0 | 0.012 |
| Tape peeling test | Presence or | — | Peeling | Peeling | Peeling | Peeling | Peeling | Peeling |
| | absence of | | absent | absent | absent | present | present | absent |
| | peeling | | | | | | | |
| Wiping test | H2 − H1 | % | −23 | −23 | −23 | −23 | −23 | 6 |
| | Peeling | — | Peeling | Peeling | Peeling | Peeling | Peeling | Peeling |
| | determination | | present | present | present | present | present | absent |
| Adhesion rank | | — | B | B | B | C | C | A |
| Withstand voltage | Encapsulation | μm | 48 | 47 | 47 | 47 | 48 | 46 |
| test | thickness | | | | | | | |
| | Average | kV | 1.4 | 1.3 | 1.3 | 0.4 | 0.5 | 1.5 |
| | withstand voltage | | | | | | | |
| | Withstand | — | A | A | A | C | C | A |
| | voltage | | | | | | | |
| | performance | | | | | | | |

| | | | | | | | |
|---|---|---|---|---|---|---|---|
| Tensile strength | MPa | 56 | 54 | 57 | 57 | 43 | 53 |

| Item | | Unit | Ex. 19 | Ex. 20 | Ex. 21 | Ex. 22 | Ex. 23 |
|---|---|---|---|---|---|---|---|
| Corona treatment of substrate | | — | — | — | — | — | — |
| Plasma treatment | Treatment | — | NH₃ | N₂/H₂ (1%) | N₂/H₂ (10%) | NH₃ | N₂ |
| conditions of | environment | | | | | | |
| substrate | Pressure | torr | 0.1 | 0.1 | 0.1 | 0.1 | 0.1 |
| | Power | kW | 11 | 3 | 3 | 1 | 3 |
| | Treatment speed | m/min | 1 | 1 | 1 | 1 | 1 |
| | Treatment time | sec | 43 | 43 | 43 | 43 | 43 |
| | Wt/F | W · sec/ | 12.6 × 10¹² | 3.0 × 10¹² | 3.0 × 10¹² | 0.8 × 10¹² | 3.0 × 10¹² |
| | | (m³/sec) | | | | | |
| Characteristic of | Contact angle | ° | 98 | 92 | 92 | 97 | 71 |
| substrate surface | O/C | — | 0.040 | 0.031 | 0.027 | 0.026 | 0.041 |
| | N/F | — | 0.011 | 0.010 | 0.050 | 0.037 | 0.020 |
| Tape peeling test | Presence or | — | Peeling | Peeling | Peeling | Peeling | Peeling |
| | absence of | | absent | absent | absent | absent | absent |
| | peeling | | | | | | |
| Wiping test | H2 − H1 | % | 4 | 6 | 6 | 6 | 6 |
| | Peeling | — | Peeling | Peeling | Peeling | Peeling | Peeling |
| | determination | | absent | absent | absent | absent | absent |
| Adhesion rank | | — | A | A | A | A | A |
| Withstand voltage | Encapsulation | μm | 48 | 46 | 46 | 46 | 46 |
| test | thickness | | | | | | |
| | Average | kV | 1.5 | 1.7 | 1.7 | 1.7 | 1.7 |
| | withstand voltage | | | | | | |
| | Withstand | — | A | A | A | A | A |
| | voltage | | | | | | |
| | performance | | | | | | |

| | | | | | | |
|---|---|---|---|---|---|---|
| Tensile strength | MPa | 40 | 54 | 55 | 56 | 56 |

In Tables 1 and 2, a numerical value in parentheses for “Treatment environment” in “Plasma treatment condition of substrate” represents a H₂ concentration (vol %) in a N₂/H₂ mixed gas.

Examples 1 to 6, 13 to 15, and 18 to 23 in which no peeling was observed in the tape peeling test were found to be excellent in withstand voltage performance. Among these, in Examples 1 to 6 and 18 to 23 in which no peeling was observed even in the wiping test, a particularly excellent withstand voltage was obtained.

Examples 1 to 6, 13 to 15, and 18 to 23 in which 0/C is within a range of 0.010 to 0.200, N/F is within a range of 0.010 to 0.100, or both ranges are satisfied were found to be excellent in withstand voltage performance.

Comparing Example 1 with Example 5, a tensile strength of a film tends to be increased by a corona treatment before a plasma treatment. Even when a strength of a plasma treatment was increased in Example 6, a good tensile strength was maintained by performing a corona treatment in advance.

The disclosure of Japanese Patent Application No. 2021-028909 is hereby incorporated by reference herein in its entirety.

All literatures, patent applications, and technical standards described herein are hereby incorporated by reference to the same extent as when individual literatures, patent applications, and technical standards are specifically and individually incorporated by reference.

### REFERENCE SIGNS LIST

1. film
2. substrate
3. antistatic layer

What is claimed is:

1. A film comprising at least a substrate and an antistatic layer,
wherein a ratio of a peeled area when a tape peeling test is performed under the following conditions after 300% uniaxial stretching at 25° C. is less than 5%,
the tape peeling test is that:
Cellotape® is pressure-bonded to a surface of the film on an antistatic layer side using a roller through 5 reciprocations with a load of 4 kg, and the Cellotape® is peeled off at a speed of 100 m/min in a direction of 180° with respect to the film within 5 minutes, thereby obtaining a ratio of a peeled area of the film to an area of an adhesive portion of the Cellotape®.

2. The film according to claim 1, wherein a relation of (H2-H1)≥0 is satisfied when a wiping test is performed under the following conditions after 300% uniaxial stretching at 25° C.,
the wiping test is that:
the film is wiped by rubbing the surface of the film on the antistatic layer side using a nonwoven fabric to which acetone is attached through 20 reciprocations with a load of 4 kg, and hazes before and after the wiping are measured at same position of the film, and a haze before the wiping is denoted by H1, and a haze after the wiping is denoted by H2.

3. The film according to claim 1, wherein O/C is within a range of 0.010 to 0.200 in surface chemical composition analysis of the substrate on an antistatic layer side by X-ray photoelectron spectroscopy.

4. The film according to claim 1, wherein N/F is within a range of 0.010 to 0.100 in surface chemical composition analysis of the substrate on the antistatic layer side by X-ray photoelectron spectroscopy.

5. A film comprising at least a substrate and an antistatic layer,
wherein a relation of (H2-H1)≥0 is satisfied when a wiping test is performed under the following conditions after 300% uniaxial stretching at 25° C.,
the wiping test is that:
the film is wiped by rubbing a surface of the film on an antistatic layer side using a nonwoven fabric to which acetone is attached through 20 reciprocations with a load of 4 kg, and hazes before and after the wiping are measured at same position of the film, and a haze before the wiping is denoted by H1, and a haze after the wiping is denoted by H2.

6. The film according to claim 5, wherein O/C is within a range of 0.010 to 0.200 in surface chemical composition analysis of the substrate on an antistatic layer side by X-ray photoelectron spectroscopy.

7. The film according to claim 5, wherein N/F is within a range of 0.010 to 0.100 in surface chemical composition analysis of the substrate on the antistatic layer side by X-ray photoelectron spectroscopy.

8. A film comprising at least a substrate and an antistatic layer,
wherein O/C is within a range of 0.010 to 0.200 in surface chemical composition analysis of the substrate on an antistatic layer side by X-ray photoelectron spectroscopy.

9. The film according to claim 8, wherein N/F is within a range of 0.010 to 0.100 in surface chemical composition analysis of the substrate on the antistatic layer side by X-ray photoelectron spectroscopy.

10. A film comprising at least a substrate and an antistatic layer,
wherein N/F is within a range of 0.010 to 0.100 in surface chemical composition analysis of the substrate on an antistatic layer side by X-ray photoelectron spectroscopy.

11. The film according to claim 1, wherein a surface of the substrate on the antistatic layer side is plasma-treated.

12. The film according to claim 1, wherein the substrate comprises at least one selected from the group consisting of a fluororesin, polymethylpentene, syndiotactic polystyrene, and a polycycloolefin.

13. The film according to claim 1, wherein the substrate comprises at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.

14. The film according to claim 1, further comprising an adhesive layer on a surface of the antistatic layer opposite to the substrate.

15. The film according to claim 1, which is a release film used in a step of encapsulating a semiconductor device with a curable resin.

16. A method for manufacturing a film, the method comprising:
plasma-treating a surface of a substrate; and
providing an antistatic layer on the plasma-treated substrate or providing an antistatic layer on the plasma-treated substrate via at least a third layer adjacent to the substrate,
wherein in surface chemical composition analysis of the substrate after the plasma treatment on an antistatic layer side by X-ray photoelectron spectroscopy, O/C is within a range of 0.010 to 0.200, N/F is within a range of 0.010 to 0.100, or both ranges of O/C and N/F are satisfied.

17. The method for manufacturing a film according to claim 16, wherein the plasma treatment is performed under a presence of an argon gas, an ammonia gas, or a nitrogen gas which may or may not comprise 10 vol % or less of a hydrogen gas.

18. The method for manufacturing a film according to claim 16, the method further comprising corona-treating the surface of the substrate before the plasma treatment.

19. The method for manufacturing a film according to claim 16, the method further comprising providing an adhesive layer on a surface of the antistatic layer opposite to the substrate.

20. A method for manufacturing a semiconductor package, the method comprising:
disposing the film according to claim 1 on an inner surface of a mold;
disposing a board including a semiconductor device in the mold in which the film is disposed;
encapsulating the semiconductor device in the mold with a curable resin to produce an encapsulated body; and
releasing the encapsulated body from the mold.

21. A method for manufacturing a semiconductor package, the method comprising:
disposing a film manufactured by the manufacturing method according to claim 16 on an inner surface of a mold;
disposing a board including a semiconductor device in the mold in which the film is disposed;
encapsulating the semiconductor device in the mold with a curable resin to produce an encapsulated body; and
releasing the encapsulated body from the mold.
